(19) United States
(12) Patent Application Publication
(10) Pub. No.: US 2011/0147872 A1
(43) Pub. Date: Jun. 23, 2011

(54) OPTICAL DEVICE, ELECTRONIC DEVICE, AND METHOD OF MANUFACTURING THE SAME

(75) Inventors: Daisuke INOUE, Osaka (JP); Kyoko FUJII, Osaka (JP); Takahiro NAKANO, Kyoto (JP); Hikari SANO, Hyogo (JP)

(73) Assignee: Panasonic Corporation, Osaka (JP)

(21) Appl. No.: 13/037,669

(22) Filed: Mar. 1, 2011

Related U.S. Application Data
(63) Continuation of application No. PCT/JP2010/000594, filed on Feb. 2, 2010.

(30) Foreign Application Priority Data
Apr. 6, 2009 (JP) 2009-092371

(51) Int. Cl. H01L 31/0232; H01L 31/18

(52) U.S. Cl. 257/432; 438/65; 257/E31.127; 257/E31.13

(57) ABSTRACT

An optical device includes a semiconductor device, a light receiving part formed on the main surface of the semiconductor device, and a transparent board laminated above the main surface of the semiconductor device, with an adhesive material interposed between the transparent board and the main surface of the semiconductor device. A serrated part is formed on at least one of (i) the main surface that is of the transparent board and faces the semiconductor device and (ii) the back surface of the transparent board.

### CROSS REFERENCE TO RELATED APPLICATION

This is a continuation application of PCT application No. PCT/JP2010/000594 filed on Feb. 2, 2010, designating the United States of America.

### BACKGROUND OF THE INVENTION

(1) Field of the Invention

The present invention relates to optical devices which detect light and the methods of manufacturing the same.

(2) Description of the Related Art

With the recent development in reduction in the dimensions, thickness, and weight of electronic devices and in enhancement in the functions of the same, the mainstream of semiconductor devices is shifting from semiconductor devices having a conventional package structure to semiconductor devices having a bare-chip structure or a chip-size package (CSP) structure. In particular, a wafer-level CSP technique has been focused which makes it possible to establish an electrical connection by forming a through electrode and re-wiring in a wafer-level chip assembly process. This technique is beginning to be used in optical devices represented by solid-state imaging devices (See PTL 1 (Patent Literature 1: Japanese Laid-open Patent Application Publication No. 2004-207461), for example).

FIG. 4 is a diagram schematically showing a cross-sectional view of a solid-sate imaging device 100A having a conventional wafer-level CSP structure.

The conventional solid-sate imaging device 100A includes a solid-state imaging device 100 including: a semiconductor device 101; an imaging device 102 formed on the main surface of the semiconductor device 101; a microlens 103 formed on the imaging device 102; a peripheral circuit region 104A formed in the periphery of the imaging device 102; and an electrode wiring 104B electrically connected to the peripheral circuit region 104A.

The semiconductor device 101 includes a transparent board 106 made of optical glass or the like formed thereabove, with an adhesive material 105 interposed between the semiconductor device 101 and the transparent board 106. The semiconductor device 101 further includes a through electrode 107 formed to penetrate through the semiconductor device 101 in the thickness direction.

Furthermore, the semiconductor device 101 includes, on its back surface, the following: a metal wiring 108 electrically connected to the through electrode 107; an insulating layer 109 that covers the back surface of the semiconductor device 101 and part of the metal wiring 108, and has an opening portion facing the remaining part of the metal wiring 108; and an external electrode 110 formed in the opening portion of the insulating layer 109, electrically connected to the metal wiring 108, and made of a solder or the like.

As described above, in the conventional solid-state imaging device 100A, the imaging device 102 and the external electrode 110 are electrically connected through the peripheral circuit region 104A, the electrode wiring 104B, the through electrode 107, and the metal wiring 108. Thus, it is possible to extract a light reception signal to a flip-chip substrate or the like.

The solid-sate imaging device 100 having the above-described structure is implemented, for example, as a camera module obtained by laminating an IR cut filter, a substrate, passive components, and optical parts such as an optical lens and a lens stop. However, due to the need of laminating plural optical parts, it had been impossible to easily achieve reduction in the height of camera modules. In view of this, there have been provided some methods of reducing the height of modules by providing, for each module, a lens on a transparent board 106 on a solid-sated imaging device 100 (See PTL 2 (Japanese Laid-open Patent Application Publication No. 2007-012995) or PTL 3 (Japanese Laid-open Patent Application Publication No. 2007-312012)).

### SUMMARY OF THE INVENTION

The solid-state imaging device 100A has a problem that only incident light beam to a region corresponding to an imaging device 102 (hereinafter referred to as “imaging region”) among incident light beam to a transparent board 106 reaches the imaging device 102 but incident light beam to a region (hereinafter referred to as “peripheral region”) outside the imaging region does not reach the imaging device 102. In other words, the amount of light received by the imaging device 102 is small with respect to the amount of incident light to the transparent board 106, resulting in a low light receiving sensitivity of the imaging device 102.

In addition, the incident light beam to the peripheral region is also irradiated on the adhesive material 105, which produces a problem in light resistance that the adhesive material 105 is degraded depending on the wavelength of the light beam.

In addition, another problem of degradation in the imaging characteristics is produced due to light reflected on the side surface of the transparent board 106, the surface of the semiconductor device 101 corresponding to the peripheral region, and the surface of the adhesive material 105. Depending on the cases, there is a need to secure a sufficiently wide distance between the imaging device 102 and the side surface of the transparent board 106. In addition to this, there is a need to form a narrow imaging region or a large solid-state imaging device 100A (form a semiconductor device 101 having enlarged dimensions, or a transparent board 106 larger than the imaging device 102).

However, in the case of forming a narrow imaging region, the number of valid pixels is reduced, which disables obtainment of a clear image. Otherwise, the dimensions of the microlens 103 are reduced, resulting in a reduced light receiving sensitivity. In contrast, in the case of forming a large solid-state imaging device 100A, the increase in the dimensions of the solid-state imaging device 100A is a problem.

The present invention has been conceived to solve the above-described conventional problems, and aims to provide optical devices and electronic devices which have excellent imaging characteristics and high reliability, and can be manufactured at low cost, and methods of manufacturing such devices.

### Solution to Problem

An optical device according to the present invention includes: a semiconductor device; a light receiving part formed on a main surface of the semiconductor device; and a transparent board laminated above the main surface of the semiconductor device, with an adhesive layer interposed between the transparent board and the main surface of the semiconductor device. In the optical device, the transparent board has a serrated part formed on a surface facing the semiconductor device.

With the aforementioned structure, it is possible to efficiently collect incident light to the transparent board on the light receiving part. Thus, the light receiving part can receive an increased amount of light yielding an increased light receiving sensitivity.

In addition, the serrated part may be formed in a range from a peripheral part of the transparent board to a center part of the transparent board. The serrated part may further include irregularities that are larger in the peripheral part than in the center part.

In addition, the serrated part may have either a Fresnel lens shape or a grating lens shape. More specifically, the serrated part may be formed with a plurality of annular protrusions arranged concentrically, the each annular protrusion having a first side surface that forms a vertical angle to the main surface of the semiconductor device and a second side surface that forms an acute angle to the main surface of the semiconductor device. Use of either one of the aforementioned structural elements makes it possible to efficiently collect light on the light receiving part, and contributes to a reduction in the height of the resulting optical device. In addition, the serrated part may include an anti-reflection film formed on the first side surface. With this, it is possible to effectively prevent light reflected on the first side surface from entering the light receiving part.

In addition, the serrated part may further include a light shielding film between the first side surface and the anti-reflection film. With this, it is possible to effectively prevent light incident from the first side surface from reaching the light receiving part.

In addition, the main surface of the semiconductor device and the first surface that is of the transparent board and faces the semiconductor device may have substantially the same dimensions. This contributes miniaturization of the resulting optical device.

In addition, the optical device may further include: a through hole penetrating through the semiconductor device in a thickness direction; an electrode region formed on the main surface and electrically connected to the light receiving part; and a through electrode having a first end in contact with a back surface of the electrode region and a second end penetrating through the semiconductor device to reach an opposing surface opposing the main surface through inside of the through hole. In addition, the through hole may include a filling layer inside. In addition, the optical device may further include an insulating layer covering the opposing surface except for at least part of the through electrode positioned on the opposing surface. In addition, the optical device may further include an external electrode formed on the opposing surface, and electrically connected to part that is of the through electrode and is not covered by the insulating layer.

In this way, a serrated part is formed in the transparent board, and a signal from the light receiving device is extracted from the back surface of the semiconductor device through the through electrode. This enables achievement of a semiconductor device having further reduced dimensions and thickness.

An electronic device according to the present invention includes: a substrate having a wired surface; and the optical device according to Claim 10 which is attached to the wired surface of the substrate, and on which the external electrode and the wiring are electrically connected. Use of the above-described optical device for an electronic device contributes reduction in dimensions and thickness of the electronic device.

An optical device according to an embodiment of the present invention includes: a semiconductor device; a light receiving part formed on a main surface of the semiconductor device; and a transparent board laminated above the main surface of the semiconductor device, with an adhesive layer interposed between the transparent board and the main surface of the semiconductor device. In the optical device, the transparent board has a serrated part formed on a second surface opposing a first surface facing the semiconductor device, the serrated part being formed in a range from a peripheral part of the transparent board to a center part of the transparent board such that irregularities are larger in the peripheral part than in the center part.

In addition, the serrated part may have either a Fresnel lens shape or a grating lens shape.

In addition, the serrated part may be formed with a plurality of annular protrusions arranged concentrically, the each annular protrusion having a first side surface that forms a vertical angle to the main surface of the semiconductor device and a second side surface that forms an acute angle to the main surface of the semiconductor device.

In addition, the serrated part includes an anti-reflection film formed on the first side surface. In addition, the optical device may further include a light shielding film between the first side surface and said anti-reflection film.

In addition, the main surface of the semiconductor device and the first surface that is of the transparent board and faces the semiconductor device have substantially the same dimensions.

An optical device manufacturing method according to the present invention is a method of manufacturing the optical device according to Claim 1. More specifically, the optical device manufacturing method involves: forming a light receiving part on a main surface of a semiconductor device; laminating a transparent board above the main surface of the semiconductor device, with an adhesive layer interposed between the transparent board and the main surface of the semiconductor device; and forming a serrated part on at least one of (i) a first surface that is of the transparent board and faces the semiconductor device and (ii) a second surface that is of the transparent board and opposes the first surface. In addition, in the forming of a serrated part, the serrated part is formed in a range from a peripheral part of the transparent board to a center part of the transparent board such that irregularities are larger in the peripheral part than in the center part.

The present invention involves forming a serrated part, and thereby making it possible to efficiently collect incident light on a light receiving part. This result in an increase in the amount of light received on the light receiving part, with an increase in the light receiving sensitivity thereof.

### Further Information about Technical Background to this Application

The disclosure of Japanese Patent Application No. 2009-092371 filed on Apr. 6, 2009 including specification, drawings and claims is incorporated herein by reference in its entirety.

The disclosure of PCT application No. PCT/JP2010/000594 filed on Feb. 2, 2010, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a cross-sectional view showing a structure of an optical device according to Embodiment 1 of the present invention;

FIG. 1B is a cross-sectional view showing a structure of an optical device that is a variation of the optical device in FIG. 1A;

FIG. 1C is an enlarged view of the serrated part shown in FIG. 1A;

FIG. 2A is a cross-sectional view showing a structure of an optical device according to Embodiment 2 of the present invention;

FIG. 2B is a cross-sectional view showing a structure of an optical device that is a variation of the optical device in FIG. 2A;

FIG. 3A is a cross-sectional view showing a structure of an optical device according to Embodiment 3 of the present invention;

FIG. 3B is a cross-sectional view showing a structure of an optical device that is a variation of the optical device in FIG. 3A; and

FIG. 4 is a cross-sectional view showing a structure of a conventional solid-state imaging device.

### DESCRIPTION OF THE PREFERRED EMBODIMENT(S)

Embodiments of the present invention are described below.

### Embodiment 1

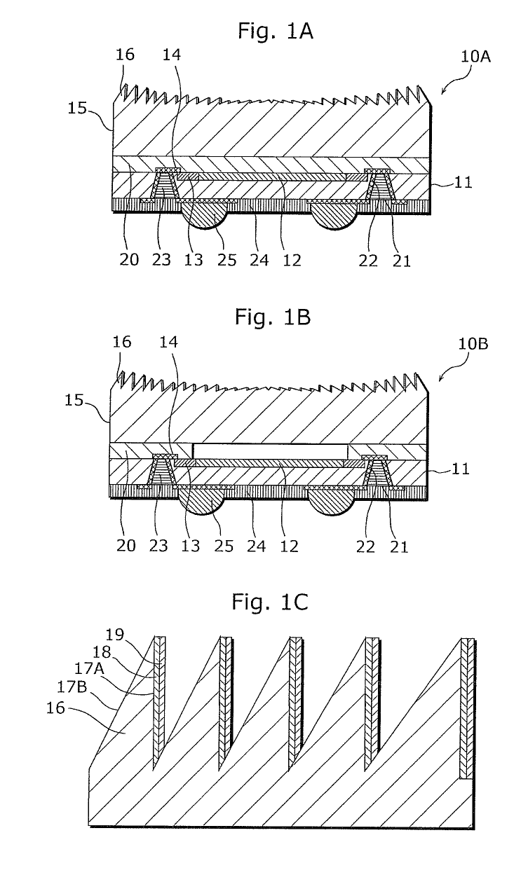

Exemplary optical devices 10A and 10B according to Embodiment 1 of the present invention are described below with reference to FIG. 1A to FIG. 1C. FIG. 1A is a cross-sectional view showing a structure of the optical device 10A according to Embodiment 1 of the present invention. FIG. 1B is a cross-sectional view showing a structure of the optical device 10B that is a variation of the optical device 10A. FIG. 1C is an enlarged view of the serrated part 16 provided in each of the optical devices 10A and 10B.

As shown in FIG. 1A, the optical device 10A includes: a semiconductor device 11; a light receiving part 12 formed on the surface (hereinafter referred to as “main surface”) of the semiconductor device 11; a peripheral circuit region 13 formed in the periphery of the light receiving part 12 and, for example, processes a signal from the light receiving part 12; an electrode region 14 formed partially using a metal thin film including Al, Cu, or the like; and a transparent board 15 laminated above the main surface of the semiconductor device 11, with an adhesive material 20 interposed between the transparent board 15 and the main surface of the semiconductor device 11.

This optical device 10A is typically a solid-state imaging device. More specifically, plural photodiodes (not shown in the drawings) are arranged in a matrix on the surface (an upper surface in FIG. 1A) of the light receiving part 12. On the upper surfaces of the plural photodiodes, microlenses (not shown in the drawings) are further arranged.

Here, the transparent board 15 is made of an optical glass, an optical resin, or the like, and a serrated part 16 is formed on the surface of the transparent board 15. In Embodiment 1, the serrated part 16 is formed on a surface (the upper surface in FIG. 1A) that is located opposite to a surface (a lower surface in FIG. 1A) that faces the semiconductor device 11 of the transparent board 15. This serrated part 16 has either a Fresnel lens shape or a grating lens shape, and the dimensions may be determined based on either the region of the light receiving part 12, desired imaging characteristics, or etc.

More specifically, the serrated part 16 is formed as plural annular protrusions arranged concentrically on the upper surface of the transparent board 15. These annular protrusions are made up of first side surfaces 17A each having a vertical angle to the main surface of the semiconductor device 11 and second side surfaces 17B each having an acute angle to the main surface of the semiconductor device 11.

The positional relationships of the first side surfaces 17A and the second side surfaces 17B are determined based on (I) the surface on which the serrated part is formed (a first surface facing the semiconductor device 11 or a second surface opposing the first surface), and (II) the magnitude relationships between (i) the refractive index of the transparent board 15 and (ii) the refractive indexes of materials each of which is in contact with the serrated part 16.

In this Embodiment 1, since the serrated part 16 is formed on the upper surface of the transparent board 15 and in contact with air (atmospheric air), the expression of “the refractive index of the transparent board 15”>“the refractive index of air” is satisfied. In this case, the inner side surface of each of the annular protrusions is a first side surface 17A, and the outer side surface of the same is a second side surface 17B.

With this structure, it is possible to collect, on the light receiving part 12, even light incident on the peripheral region of the transparent board 15. In short, the serrated part 16 functions as a light collecting lens that collects light on the light receiving part 12.

It is also good to vary, for each annular protrusion, the angle of the second side surface 17B of the serrated part 16 to the semiconductor device 11. In Embodiment 1, such angles are smaller as the positions of the annular protrusions are closer to the center part (inner side), and larger as the positions of the same are closer to the peripheral part (outer side).

Alternatively, as in the case of a grating lens shape, it is good to increase the intervals between adjacent annular protrusions as the positions are closer to the center part (inner side), and decrease the same as the positions are closer to the peripheral part (outer side). At this time, in order to prevent stray light from being collected on the imaging region and increase the diffraction indexes, it is desirable that each of the annular protrusions that constitute the serrated part 16 is formed to have an outer side surface as a first side surface 17A and an inner side surface as a second side surface 17B. In addition, it is also good to modify the height of the saw teeth as necessary so that a light beam is enhanced by an arbitrary wavelength or an arbitrary diffraction order. Alternatively, it is possible to stack plural transparent boards 15 including a serrated part 16 in order to increase the diffraction efficiencies of not only the arbitrary wavelength but also other wavelengths.

In addition, as shown in FIG. 1C, it is also good to form a light shielding film 18 and an anti-reflection film 19 on the first side surface 17A of the serrated part 16. The light shielding film 18 is made of a metal such as Al, Cr, and/or Au. The anti-reflection film 19 may be formed using either an inorganic material or an organic material. It is desirable that a light shielding film 18 is formed first on the first side surface 17A, and the anti-reflection film 19 is laminated on the light shielding film 18.

Here, it is possible to form only the anti-reflection film 19 on the first side surface 17A, or to form only the light shielding film 18 instead. Furthermore, it is also possible to form a single light shielding and anti-reflection film that has both light shielding and reflection prevention characteristics instead of forming both the light shielding film 18 and the anti-reflection film 19. For example, it is desirable that a film mainly made of CrO is formed.

The adhesive material 20 may be formed, using a resin material, to cover the whole main surface of the semiconductor device 11 as in the optical device 10A shown in FIG. 1A, or may be formed on only the region (peripheral region) except for the light receiving part 12 as in the optical device 10B shown in FIG. 1B. In other words, the optical device 10B may have a cavity structure in which a cavity is present between the light receiving part 12 and the transparent board 15. An appropriate adhesive material 20 may be selected based on the electric characteristics and imaging characteristics of the optical devices 10A and 10B, the region (imaging region) and resistance to light of the light receiving part 12, and the adhesive strength between the semiconductor device 11 and the transparent board 15. In addition, the optical device 10A further includes: a through hole 21 formed immediately below the electrode region 14 to penetrate through the semiconductor device 11 in the thickness direction (the through hole 21 has, for example, a thickness of 100 to 300 μm); and a through electrode 22 formed to across a part of the back surface (the lower surface in FIG. 1A) of the semiconductor device 11 and inside the through hole 21.

Here, the through electrode 22 is made of metal such as Ti and Cu, and is electrically connected to the electrode region 14. In addition, the through hole 21 is filled with a filling layer 23 made of resin or the like. Here, the through electrode 22 may cover only the inner surface of the through hole 21 as in FIG. 1A, or fully fill the through hole 21 in place of the filling layer 23.

In addition, on the back surface of the semiconductor device 11, an insulating layer 24 is formed which covers the through electrode 22 and has an opening portion. In other words, the insulating layer 24 is formed to avoid at least a part of the through electrode 22 located on the back surface of the semiconductor 11, and thus the part of the through electrode 22 is exposed from the insulating layer 24.

This insulating layer 24 is made using, for example, a resin material. In addition, in the opening portion of the insulating layer 24, an external electrode 25 is formed which is electrically connected to the through electrode 22. This external electrode 25 is made using, for example, a lead-free solder material having a composition of Sn—Ag—Cu.

In other words, the through electrode 22 has a first end that is in contact with the back surface of the electrode region 14, and has a second end that is electrically connected to the external electrode 25 through the through hole 21. In this way, the electrode region 14 is electrically connected to the external electrode 25 via the through electrode 22. This makes it possible to extraction of the light reception signal in the optical devices 10A and 10B according to Embodiment 1.

As described above, with the optical devices 10A and 10B according to Embodiment 1 shown in FIG. 1A and FIG. 1B, it is possible to efficiently collect incident light on the light receiving part 12 utilizing the serrated part 16 formed on the transparent board 15. This increases the amount of received light, with an increase in the light receiving sensitivity. Furthermore, it is possible to reduce the height of the optical devices 10A and 10B more significantly than in the case of forming a convex lens on the transparent board 15.

Furthermore, in the serrated part 16, it is possible to prevent incident light and reflected light from the side surface of the transparent board 15 from entering the light receiving part 12 by adjusting the angle between the main surface of the semiconductor device 11 and the second side surface 17B. As a result, it is possible to reduce degradation in imaging characteristics of the optical device as the solid-state imaging device. In addition, it is possible to reduce the distance between the light receiving part 12 and the side surface of the transparent board 15, which enlarges the dimensions of the light receiving region and increases the light receiving sensitivity. It is also possible to reduce the surface dimensions of the semiconductor device 11 maintaining the dimensions of the light receiving region, which enables miniaturization of the optical device 10A.

In addition, in the case of forming a serrated part 16 having a Fresnel lens shape, it is possible to collect light on the imaging region more efficiently and reduce the height of the optical device 10A by varying, for each annular protrusion, the angle of the second side surface 17B to the main surface of the semiconductor device 11.

In the case of forming a serrated part 16 having a grating lens shape, it is desirable that the intervals between adjacent annular protrusions are set to be larger as the positions thereof are closer to the center part (inner side), and to be smaller as the positions thereof are closer to the peripheral part (outer side). In this way, it is possible to collect light on the imaging region by diffraction of light, and reduce the height of the optical device 10A. In addition, stacking plural transparent boards 15 each having a serrated part 16 achieves a high diffraction efficiency in each of plural wavelength, and thereby making it possible to collect light on the imaging region more efficiently.

The adhesive material 20 reduces, functioning as a buffer, a compression load due to insertion of a probe in a test using the probe. Such compression load can be reduced particularly in the case where the adhesive material 20 is formed to cover the whole main surface of the semiconductor device 11 as in FIG. 1A. As a result, it is possible to obtain an optical device 10A having an excellent transverse strength.

Furthermore, since incident light from the side surface of the transparent board 15 is prevented, in the structure including a cavity as shown in FIG. 1B, the amount of incident light beam to the adhesive material 20 located in the peripheral region is reduced. As a result, there is no need to consider resistance to light of the adhesive material 20 also in the case where a wavelength that degrades the characteristics of the adhesive material 20 is included therein. This enlarges the range of options as an adhesive material 20, which enables cost reduction.

Providing an anti-reflection film 19 to the first side surface 17A of the serrated part 16 makes it possible to prevent entering of reflected light from the first side surface 17A. Forming a film that shields light and prevents reflection making it possible to prevent entering of reflected light and incident light from the first side surface 17A. As a result, it is possible to further enhance the imaging characteristics of the optical device as the solid-state imaging device.

The optical devices 10A and 10B illustrated in Embodiment 1 are more excellent in the light receiving sensitivity and imaging characteristics than conventional, and have dimensions and a height reduced more significantly than conventional.

The optical device 10B shown in FIG. 1B is basically the same as the optical device 10A shown in FIG. 1A except for the point of having a cavity (cavity structure) immediately above the light receiving part 12. Thus, detailed descriptions thereof are not repeated. Naturally, the optical device 10B can also provide the aforementioned same advantageous effects.

### Embodiment 2

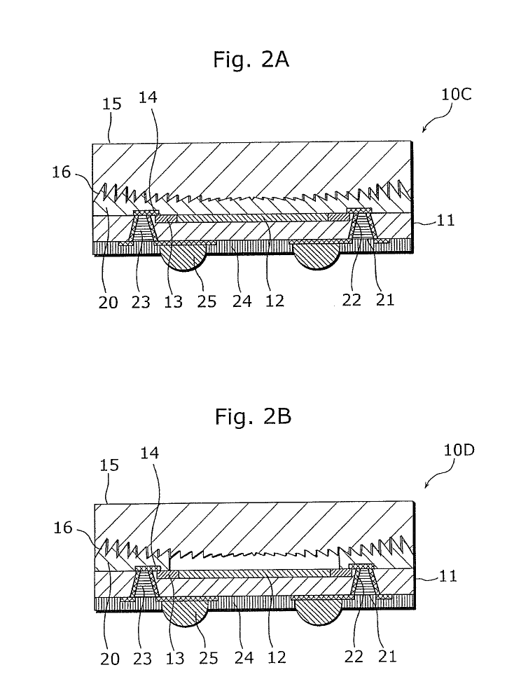

Optical devices 10C and 10D according to Embodiment 2 of the present invention are described below with reference to FIG. 2A and FIG. 2B. FIG. 2A is a cross-sectional view showing a structure of the optical device 10C according to Embodiment 2 of the present invention. FIG. 2B is a cross-sectional view showing a structure of an optical device 10D that is a variation of the optical device 10C.

As shown in FIG. 2A and FIG. 2B, the optical devices 10C and 10D are different from the optical devices 10A and 10B in Embodiment 1 in including a serrated part 16 on a surface that is of the transparent board 15 and faces the semiconductor device 11. Thus, the difference from the earlier-described embodiment is focused in the following descriptions. The structural elements common in FIG. 1A to FIG. 2B are assigned with the same reference signs, and the descriptions thereof are not repeated.

As shown in FIG. 2A, the optical device 10C according to Embodiment 2 includes the serrated part 16 on the surface (the lower surface in FIG. 2A) that is of the transparent board 15 and faces the semiconductor device 11. In other words, the serrated part 16 of the transparent board 15 is formed to face the main surface of the semiconductor device 11, with an adhesive material 20 interposed between the serrated part 16 and the main surface of the semiconductor device 11.

Here, the adhesive material 20 may be formed to cover the whole main surface of the semiconductor device 11 as shown in FIG. 2A. Alternatively, the adhesive material 20 may be formed on a region (peripheral region) except for a region (imaging region) immediately above the light receiving part 12. In other words, the optical device 10D may have a cavity structure in which a cavity is present between the light receiving part 12 and the transparent board 15. An appropriate adhesive material 20 may be selected based on the electric characteristics and imaging characteristics of the optical devices, the region (imaging region) of the light receiving part 12, and so on.

The dimensions of the serrated part 16, the refractive index of the adhesive material 20, and the thickness of the adhesive material 20 may be appropriately selected based on the imaging characteristics of the optical devices 10C and 10D, the region of the light receiving part 12, and so on, on a precondition that the expression of “the refractive index of the transparent board 15”≠“the refractive index of the adhesive material 20” is satisfied.

In Embodiment 2, the outer side surface of each of the annular protrusions that constitute the serrated part 16 is a first side surface 17A, and the inner side surface of the same is a second side surface 17B, on preconditions that the serrated part 16 is formed in the lower surface side of the transparent board 15 and that the expression of “the refractive index of the transparent board 15”<“the refractive index of the adhesive material 20” is satisfied.

The serrated part 16 has a Fresnel lens shape in which the angles of the respective second side surfaces 17B to the main surface of the semiconductor device 11 are smaller as the positions thereof are closer to the center part (inner side) and larger as the positions thereof are closer to the peripheral part (outer side).

Alternatively, as in the case of a serrated part 16 having a grating lens shape, it is good to increase the intervals between adjacent annular protrusions as the positions thereof are closer to the center part (inner side), and decrease the same as the positions thereof are closer to the peripheral part (outer side). At this time, in order to prevent stray light from being collected on the imaging region and increase the diffraction indexes, it is desirable that each of the annular protrusions that constitute the serrated part 16 is formed to have an inner side surface as a first side surface 17A and an outer side surface as a second side surface 17B, on a precondition that the expression of “the refractive index of the transparent board 15”≠“the refractive index of the adhesive material 20” is satisfied. In addition, it is also good to modify the height of the saw teeth as necessary so that light beams are mutually enhanced by arbitrary wavelengths or diffraction orders. Alternatively, it is possible to stack plural transparent boards 15 each including a serrated part 16 in order to increase the diffraction efficiencies of not only the arbitrary wavelength but also other wavelengths.

With this structure, the optical device 10C provides advantageous effects as indicated below, in addition to the advantageous effects described in Embodiment 1.

The serrated part 16 is formed in the lower surface side of the transparent board 15 to face the main surface of the semiconductor device 11 through the adhesive material 20. Use of this serrated shape increases the dimensions of a contact surface between the semiconductor device 11 and the adhesive material 20. In this way, it is possible to increase the adhesion force between the semiconductor device 11 and the transparent board 15. This increases the share strength and so on between the semiconductor device 11 and the transparent board 15. Such enhancement in adhesion force is remarkable particularly in the optical device 10C as shown in FIG. 2A.

In the case of forming a serrated part 16 having a grating lens shape, it is only necessary to select an appropriate adhesive agent on a precondition that the expression of “the refractive index of the transparent board 15”≠“the refractive index of the adhesive material 20” is satisfied. Since the range of options as an adhesive material 20 is enlarged, cost reduction is enabled.

The optical device 10D shown in FIG. 2B is basically the same as the optical device 10C shown in FIG. 2A except for the point of having a cavity (cavity structure) immediately above the light receiving part 12. Thus, detailed descriptions thereof are not repeated. Naturally, the optical device 10D can also provide the aforementioned same advantageous effects.

### Embodiment 3

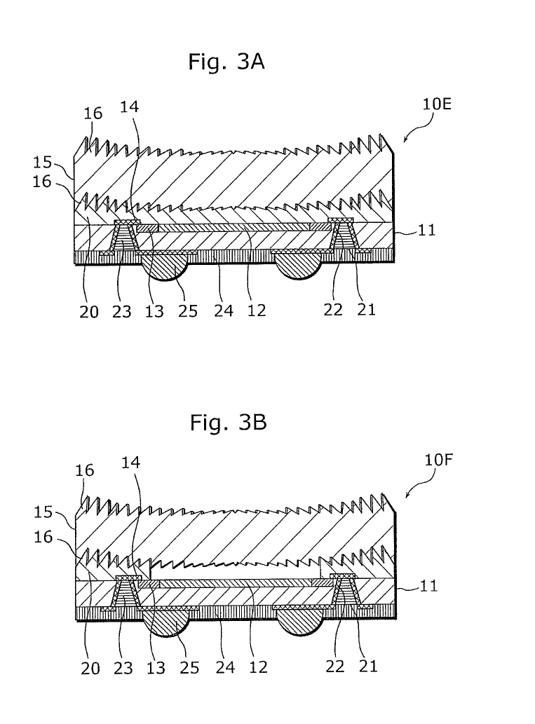

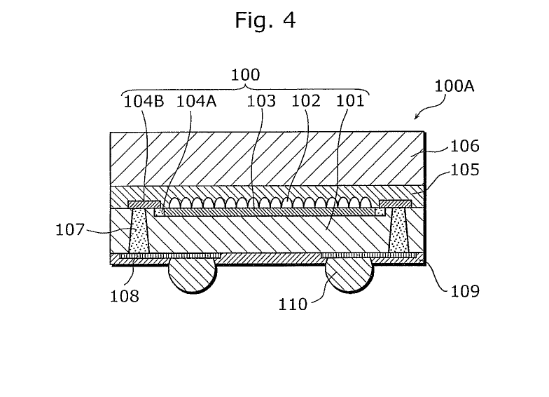

Optical devices 10E and 10F according to Embodiment 3 of the present invention are described below with reference to FIG. 3A and FIG. 3B. FIG. 3A is a cross-sectional view showing a structure of the optical device 10E according to Embodiment 3 of the present invention. FIG. 3B is a cross-sectional view showing a structure of an optical device 10F that is a variation of the optical device 10E.

As shown in FIG. 3A and FIG. 3B, the optical devices 10E and 10F are different from the optical device 10A in Embodiment 1 in including a serrated part 16 on each of the upper surface and the lower surface of the transparent board 15. Thus, the difference from each of the earlier-described embodiments is focused in the following descriptions. The structural elements common in FIG. 1A to FIG. 3B are assigned with the same reference signs, and the descriptions thereof are not repeated.

As shown in FIG. 3A, the optical device 10E according to Embodiment 3 includes a serrated part 16 on each of the upper surface and the lower surface of the transparent board 15. Here, it is possible to form a serrated part 16 on the upper surface of the transparent board 15 as in Embodiment 1, and form a serrated part 16 on the lower surface of the transparent board 15 as in Embodiment 2. The dimensions of each of the serrated parts 16, the refractive index of each of the adhesive materials 20, and the thickness of each of the adhesive materials 20 may be appropriately selected based on the imaging characteristics of the optical device 10E, the region of the light receiving part 12, and so on, assuming that the relationship between the refractive index of the transparent board 15 and the refractive index of the adhesive material 20 is the same as in Embodiment 2.

The optical device including the serrated parts 16 on the upper and lower surfaces of the transparent board 15 provides an advantageous effect of being able to collect light on the light receiving part 12 more efficiently, in addition to the advantageous effects described in Embodiments 1 and 2. Thus, the light receiving sensitivity of the light receiving part 12 is increased.

The optical device 10F shown in FIG. 3B is basically the same as the optical device 10E shown in FIG. 3A except for the point of having a cavity (cavity structure) immediately above the light receiving part 12. Thus, detailed descriptions thereof are not repeated. Naturally, the optical device 10F can also provide the aforementioned same advantageous effects.

### (Methods of Manufacturing the Exemplary Optical Devices Described in the Respective Embodiments)

A method of manufacturing optical devices 10A according to Embodiment 1 is described below. This manufacturing method includes a dispersion process, a process of forming a serrated part, a process of forming an anti-reflection film, a process of attaching a transparent board, a back grinding process, a process of forming a through electrode, a process of forming a solder ball, a dicing process, and so on. It is to be noted that the processing order of the aforementioned processes are arbitrarily changed except for a part of the processes.

The method of manufacturing the optical devices 10A is described with reference to FIG. 1A. First, a wafer including plural semiconductor devices 11 is prepared. It is assumed that the respective semiconductor devices 11 are formed according to a known method, and that each of the semiconductor devices 11 includes, on the main surface, a light receiving part 12, a peripheral circuit region 13, and an electrode region 14. Here, the electrode region 14 includes a metal thin film made of Al, Cu, or the like.

Next, a serrated part 16 is formed on the upper surface of the transparent board 15. More specifically, plural annular protrusions are formed concentrically on the upper surface of the transparent board 15; the plural annular protrusions are made of first side surfaces 17A each forming a vertical angle to the main surface of the semiconductor device 11 and second side surfaces 17B each forming an acute angle to the same.

Such serrated part 16 is formed, for example, according to an embossing method using a metal frame or a cutting method using a single point tool. Alternatively, it is possible to attach a lens sheet on which a lens shape is formed in advance.

Embossing using a metal frame is excellent in processing time and cost because this allows to form a serrated part 16 on the whole main surface of the transparent board 15 at one time. In the case of attaching a lens sheet, although it does not matter whether the lens sheet is formed using an organic material or using an inorganic material, it is desirable that the refractive index of the lens sheet is the same as the refractive index of the transparent board 15. In this way, it is possible to prevent reflection and refraction of incident light on the adhesion interface between the transparent board 15 and the lens sheet.

Subsequently, an anti-reflection film 19 is formed on the first side surface 17A of the serrated part 16. An exemplary method used to form an anti-reflection film 19 is a method of depositing the anti-reflection film 19 on the transparent board 15 using a CVD method. First, a dielectric film made of SiN or the like is deposited on the whole main surface of the transparent board 15 using the CVD method. Next, in order to form an arbitrary shape, Sin on the part except for the first side surface 17A is removed according to reactive ion etching (RIE) using, for example, a CF reactive gas. In this way, it is possible to prevent reflected light from the first side surface 17A, and increase the imaging characteristics of the optical device as the solid-state imaging device.

The following describes a case of forming a light shielding film 18 and an anti-reflection film 19 on the first side surface 17A. First, a metal film made of Al, Cr, Au, or the like is deposited on the whole main surface of the transparent board 15 using a PVD method or a CVD method. Next, the metal film on the part except for the first side surface 17A is removed according to ion etching. Next, the anti-reflection film 19 is formed according to the aforementioned method. The following describes an alternative case of forming, in an arbitrary shape, a single film that has both light shielding characteristics and reflection prevention characteristics. First, CrO is deposited on the whole main surface of the transparent board 15 using a CVD method or a reactive sputtering method. Next, the CrO on the part except for the first side surface 17A is removed according to ion etching.

Next, an adhesive material 20 made of resin is applied on the plural semiconductor devices 11 in a wafer form and adhere (stack) the semiconductor devices 11 and transparent boards 15 in a wafer form. Alternatively, it is possible to apply such an adhesive material 20 to transparent boards 15 in a wafer form and adhere the transparent boards 15 to the semiconductor devices 11 in a wafer form. Methods available as a method of applying such an adhesive material 20 include a spin coating method, a printing and filling method, and a dispenser method. In the case of using the spin coating method when applying the adhesive material 20 in an optical device 10B having a cavity structure as shown in FIG. 1B, it is desirable to use a photosensitive adhesive material 20 and perform patterning according to photolithography.

Here, it is also good to adhere the semiconductor devices 11 in a wafer form and transparent boards 15 in a wafer form, and then form, on the main surface of each of the transparent board 15, a serrated part 16, an anti-reflection film 19, etc.

Next, it is desirable that the wafer is subjected to back grinding to a desired thickness (in general, approximately 100 to 300 μm), and then to mirror finish such as chemical mechanical polishing (CMP).

Next, a through hole 21 is formed to penetrate through the semiconductor 11 from the back surface of the semiconductor 11 in the thickness direction to reach the back surface of the electrode region 14. More specifically, it is only necessary to perform dry etching, wet etching, or the like using, as a mask, either a resist, SiO₂, a metal film, or the like.

Next, an insulating film (not shown in FIG. 1A to FIG. 1C) such as SiO₂ is formed on the whole back surface of the semiconductor device 11, and inside the semiconductor device 11 and the through hole 21, according to a CVD (chemical vapor deposition) method, an insulating paste printing and filling method, or the like.

Next, the insulating film formed on the electrode region 14 is removed re-using dry etching, wet etching, or the like. Next, a through electrode 22 is formed which extends from inside the through hole 21 to the back surface of the semiconductor device 11. For example, a metal thin film is formed on the whole main surface of the semiconductor device 11 using the sputtering method or the like.

Here, as a metal thin film, Ti, TiW, Cr, Cu, or the like is used. After a liquid photosensitive resist is provided by attaching a dry film or by performing spin coating, pattering is performed by exposure and development according to photolithography to form a resist pattern suitable for the through electrode 22. Here, the thickness of the resist may be determined based on the thickness of a through electrode 22 to be finally desired. In general, the thickness is approximately 5 to 30 μm. Next, the through electrode 22 is formed using a metal such as Cu according to an electro plating method.

Next, a filling layer 23 is formed in the through hole 21 in which the through electrode 22 is formed. Metal or resin may be used as a filling material. In the case of filling metal, it is only necessary to fill metal using an electro plating method or fill mainly a metal paste using a printing and filling method, dipping, or the like.

In the case of filling using the electro plating method, it is desirable to perform the filling at the same time when the through electrode 22 is formed. At this time, the filling layer 23 is filled to fully embed the through hole 21. The following describes an alternative case of forming a filling layer 23 and a through hole 22 separately. For example, a through electrode 22 is formed first, then a mask having an opening in a part corresponding to the through hole 21 is formed, and then a filling layer 23 is formed in the through hole 21 using the electro plating method.

In the case of filling a resin material, it is good to fill a liquid light hardening resin or a liquid heat hardening resin by spin coating, or to fill a resin paste using a printing and filling method, dipping, or the like.

Next, an insulating layer 24 is formed on the back surface of the semiconductor device 11 to cover the through electrode 22. For example, the insulating layer 24 is formed by spin coating a photosensitive resin or by attaching a dry film of a photosensitive resin. Next, an opening portion for exposing a part of the through electrode 22 is formed by selectively removing part of the insulating layer 24 using a photolithography technique.

Next, an external electrode 25 which is electrically connected to the electrode region 14 is formed on the opening portion in the through electrode 22, according to a solder ball mounting method using a flax, a solder paste printing method, or an electro plating method. As this material, a metal-free solder material having a composition of Sn—Ag—Cu may be used for example.

Next, the wafer including plural semiconductor devices 11 is cut into segments as individual optical devices 10A, using a cutting member such as a dicing saw. Here, it is also good to segment the wafer into plural semiconductor devices 11 first, pick up each of the semiconductor devices 11, and then attach each semiconductor device 11 to a transparent board 15. In this way, the semiconductor device 11 and the transparent board 15 has the substantially same dimensions. In other words, the main surface of the semiconductor device 11 and the surface that is of the transparent board 15 and faces the semiconductor device 11 have the substantially same dimensions. Here, “substantially the same” means that a certain degree of difference is allowed, and the difference is, for example, 3% or smaller, more preferably, 1% or smaller.

Next, as for the optical devices 10C, 10D, 10E, and 10F in Embodiments 2 and 3, the differences from the above-described manufacturing method are described below. The main difference is the processing order of processes in the manufacturing method, and thus the methods of forming the shapes are not repeatedly detailed.

First, each of the optical devices 10C and 10D shown in FIG. 2A and FIG. 2B includes a serrated part 16 in the lower surface side of the transparent board 15. In other words, the serrated part 16 of the transparent board 15 is formed to face the main surface of the semiconductor device 11, with an adhesive material 20 interposed between the serrated part 16 and the main surface of the semiconductor device 11. For this formation, the serrated part 16 is formed in the lower surface side of the transparent board 15 first, and the semiconductor device 11 and the transparent board 15 are adhered to each other such that the serrated part 16 of the transparent board 15 faces the semiconductor device 11 through the adhesive material 20.

In addition, each of the optical devices 10E and 10F shown in the corresponding one of FIG. 3A and FIG. 3B includes a serrated part 16 in each of the upper and lower surface side of the transparent board 15. For this formation, the serrated part 16 is formed in each of the upper and lower surface sides of the transparent board 15 first, and the semiconductor device 11 and the transparent board 15 are adhered to each other such that the serrated parts 16 of the transparent board 15 faces the semiconductor device 11 through the adhesive material 20. Alternatively, it is possible to form a serrated part 16 in the lower surface side of the transparent board 15, adhere the semiconductor device 11 and the transparent board 15 such that the serrated part 16 of the transparent board 15 faces the semiconductor device 11 through the adhesive material 20, and lastly form a serrated part 16 in the lower surface side of the transparent board 15.

Although exemplary embodiments of the present invention have been described above with reference to the drawings, the present invention is not limited to these illustrated embodiments. Those skilled in the art will readily appreciate that many modifications and variations are possible using the illustrated embodiments without materially departing from the novel teachings and advantages of the present invention. Accordingly, all such modifications and variations are intended to be included within the scope of the present invention.

### INDUSTRIAL APPLICABILITY

Semiconductor devices according to the present invention are particularly suitable for optical devices (especially for solid-state imaging devices, various kinds of semiconductor devices or modules such as photodiodes and laser modules).

1. An optical device comprising:
a semiconductor device;
a light receiving part formed on a main surface of said semiconductor device; and
a transparent board laminated above the main surface of said semiconductor device, with an adhesive layer interposed between said transparent board and the main surface of said semiconductor device,
wherein said transparent board has a serrated part formed on at least one of a first surface facing said semiconductor device and a second surface opposing the first surface.

2. The optical device according to claim 1,
wherein said serrated part is formed in a range from a peripheral part of said transparent board to a center part of said transparent board.

3. The optical device according to claim 1,
wherein said serrated part includes irregularities that are larger in the peripheral part than in the center part.

4. The optical device according to claim 1,
wherein said serrated part has either a Fresnel lens shape or a grating lens shape.

5. The optical device according to claim 4,
wherein said serrated part is formed with a plurality of annular protrusions arranged concentrically, said each annular protrusion having a first side surface that forms a vertical angle to the main surface of said semiconductor device and a second side surface that forms an acute angle to the main surface of said semiconductor device.

6. The optical device according to claim 5,
wherein said serrated part includes an anti-reflection film formed on the first side surface.

7. The optical device according to claim 6,
wherein said serrated part further includes a light shielding film between the first side surface and said anti-reflection film.

8. The optical device according to claim 1,
wherein the main surface of said semiconductor device and the first surface that is of the transparent board and faces said semiconductor device have substantially the same dimensions.

9. The optical device according to claim 1, further comprising:
a through hole penetrating through said semiconductor device in a thickness direction;
an electrode region formed on the main surface and electrically connected to said light receiving part; and
a through electrode having a first end in contact with a back surface of said electrode region and a second end penetrating through said semiconductor device to reach an opposing surface opposing the main surface through inside of said through hole.

10. The optical device according to claim 9,
wherein said through hole includes a filling layer inside.

11. The optical device according to claim 9, further comprising
an insulating layer covering the opposing surface except for at least part of said through electrode positioned on the opposing surface.

12. The optical device according to claim 11, further comprising
an external electrode formed on the opposing surface, and electrically connected to part that is of said through electrode and is not covered by said insulating layer.

13. An electronic device comprising:
a substrate having a wired surface; and
the optical device according to claim 12 which is attached to the wired surface of said substrate, and on which said external electrode and said wiring are electrically connected.

14. An optical device comprising:
a semiconductor device;
a light receiving part formed on a main surface of said semiconductor device; and
a transparent board laminated above the main surface of said semiconductor device, with an adhesive layer interposed between said transparent board and the main surface of said semiconductor device,
wherein said transparent board has a serrated part formed on a second surface opposing a first surface facing said semiconductor device, said serrated part being formed in a range from a peripheral part of said transparent board to a center part of said transparent board such that irregularities are larger in the peripheral part than in the center part.

15. The optical device according to claim 14,
wherein said serrated part has either a Fresnel lens shape or a grating lens shape.

16. The optical device according to claim 15,
wherein said serrated part is formed with a plurality of annular protrusions arranged concentrically, said each annular protrusion having a first side surface that forms a vertical angle to the main surface of said semiconductor device and a second side surface that forms an acute angle to the main surface of said semiconductor device.

17. The optical device according to claim 16,
wherein said serrated part includes an anti-reflection film formed on the first side surface.

18. The optical device according to claim 16,
wherein said serrated part further includes a light shielding film between the first side surface and said anti-reflection film.

19. The optical device according to claim 1,
wherein the main surface of said semiconductor device and the first surface that is of the transparent board and faces said semiconductor device have substantially the same dimensions.

20. A method of manufacturing an optical device, said method comprising:
forming a light receiving part on a main surface of a semiconductor device;
laminating a transparent board above the main surface of the semiconductor device, with an adhesive layer interposed between said transparent board and the main surface of said semiconductor device; and
forming a serrated part on at least one of (i) a first surface that is of the transparent board and faces the semiconductor device and (ii) a second surface that is of the transparent board and opposes the first surface,
wherein, in said forming of a serrated part, the serrated part is formed in a range from a peripheral part of the transparent board to a center part of the transparent board such that irregularities are larger in the peripheral part than in the center part.

21. The optical device according to claim 10, further comprising
an insulating layer covering the opposing surface except for at least part of said through electrode positioned on the opposing surface.

22. The optical device according to claim 21, further comprising
an external electrode formed on the opposing surface, and electrically connected to part that is of said through electrode and is not covered by said insulating layer.

23. An electronic device comprising:
a substrate having a wired surface; and
the optical device according to claim 22 which is attached to the wired surface of said substrate, and on which said external electrode and said wiring are electrically connected.
